(19) United States
(12) Patent Application Publication
(10) Pub. No.: US 2012/0104606 A1
(43) Pub. Date: May 3, 2012

(54) BALL GRID ARRAY SEMICONDUCTOR DEVICE AND ITS MANUFACTURE

(75) Inventors: Hayato OKUDA, Aizuwakamatsu (JP); Yasunori Kawaoka, Aizuwakamatsu (JP); Akira Takashima, Aizuwakamatsu (JP)

(73) Assignee: FUJITSU SEMICONDUCTOR LIMITED, Yokohama-shi (JP)

(21) Appl. No.: 13/218,153

(22) Filed: Aug. 25, 2011

(30) Foreign Application Priority Data
Nov. 2, 2010 (JP) 2010-246357

(51) Int. Cl. H01L 23/498; H01L 21/60

(52) U.S. Cl. 257/738; 438/107; 257/E23.069; 257/E21.508

(57) ABSTRACT

A semiconductor device includes: stacked semiconductor chips having respective input/output pads on surfaces thereof; a lower resin body molding the lower semiconductor chip and having a surface coplanar with the lower chip; an upper resin body molding the upper chip and coupled with the first resin body; wirings connected to input/output pads of the lower or upper chip and extending horizontally; external connection metal posts formed on the wirings and having tops exposed from the second resin body; and ball-shaped external connection terminals connected to the tops of the external connection metal posts.

### CROSS REFERENCE TO RELATED APPLICATIONS

This application is based upon and claims the benefit of priority of the prior Japanese Patent Application No. 2010-246357, filed on Nov. 2, 2010, the entire contents of which are incorporated herein by reference.

### FIELD

The embodiments of the present invention relate to a semiconductor device and its manufacture method.

### BACKGROUND

Requests for miniaturization of electronic devices are strong. Requests for improving integration of semiconductor devices to be accommodated in electronic devices are continuing. If a plurality of chips can be stacked and mounted on a place where a single chip was mounted, an electronic device can be made further compact. Various structures have been proposed having a ball grid array (BGA) in which a plurality of semiconductor chips are stacked in a system in package (SiP) or the like and external connection terminals such as solder balls are located in an array configuration on one principal surface. In stacking a plurality of chips, there arises a problem of how inter-chip electric connections are realized.

JP-2004-140037 Publication proposes that in a wafer state, metal posts are formed on an upper surface of a peripheral area of each lower semiconductor chip, an upper semiconductor chip is dice-bonded via an adhesive tape to an upper surface of a central area of each lower semiconductor chip, a sealing resin layer is formed covering the upper semiconductor chip and metal posts, and thereafter the electrodes of an upper semiconductor chip and the upper surfaces of the metal posts are exposed, a rewiring layer is formed, metal posts are formed on the rewiring layer, the devices are sealed with resin, the upper surfaces the metal posts are exposed, ball electrodes are formed on the metal posts and thereafter the semiconductor wafer is diced together with sealing resin to form an individual semiconductor device. In the state after dicing, the side walls and bottom of a lower semiconductor chip made of the diced semiconductor wafer are exposed.

A semiconductor chip is likely to be influenced by moisture or the like, and it is preferable to provide a packaging structure for covering at least the upper surface and side walls of a semiconductor chip. Several packaging methods have been adopted. Plastic molding is packaging of low manufacture cost and high reliability.

For plastic molding using a lead frame made of iron alloy such as 42 alloy, copper, copper alloy or the like, a semiconductor chip is die-bonded to a die pad of a lead frame, and the input/output pads of the semiconductor chip and leads of the lead frame are interconnected by wire bonding. Thereafter, the lead frame is mounted on a mold and an injection mold is formed, using sealing resin. Distal ends of the leads may be pulled down and led to a surface of the sealing resin, and solder balls may be connected to the exposed surface of the leads. The lead frame is made of a single plate member so that leads of the lead frame are disposed in the peripheral area of the semiconductor chip. There is therefore a limit in an increase in the number of leads.

There is another method using an interposer having wirings, instead of a lead frame. For example, a semiconductor chip is die-bonded on a die pad on an upper surface of an interposer such as a glass epoxy substrate with multi-layer copper wirings and a ball grid array (BGA) formed on the lower surface thereof, and the input/output pads of the semiconductor chip and electrodes of the interposer are interconnected by wire bonding. The semiconductor chip and the bonding wires are molded in sealing resin to thereby form a BGA type semiconductor device.

The lead frame and interposer may be collectively called an interposer in some cases. The interposer extends also outside the semiconductor device to provide physical support during the resin mold process, and unnecessary portion should be cut off after the mold process. An interface between the molding resin and interposer is therefore exposed at the facet of the package.

FIG. 8A is a cross sectional view of a semiconductor device disclosed in JP-A-2007-134731. Two semiconductor chips are stacked on the upper surface of an interposer having BGA formed on the lower surface thereof, the electrodes of the two semiconductor chips and interposer are interconnected by wire bonding, and sealing resin is used to form a mold of two semiconductor chips and interposer. The semiconductor device 110 is constituted of a first semiconductor chip 111, a second semiconductor chip 112, an interposer 113, a sealing resin body 116, solder balls 117 and the like. The semiconductor device 110 is a multi-chip package (MCP) type semiconductor device having the second semiconductor chip 112 staked on the first semiconductor chip 111.

The first semiconductor chip 111 is bonded via a die attachment film 170 to the interposer 113, and the second semiconductor chip 112 is bonded via a die attachment film 180 to the first semiconductor chip 111. The bonding pads 115 of the first and second semiconductor chips 111 and 112 and the electrodes 120 of the interposer 113 are interconnected by bonding wires 114. Sealing resin 116 is used to form a mold of the first and second semiconductor chips 111 and 112 and bonding wires 114. An interface between the interposer 113 and sealing resin 116 is therefore exposed at the sidewall of the semiconductor package.

FIG. 8B is a cross sectional view of a semiconductor device disclosed in JP-A-2008-91418. This package is a multi-chip package using a lead frame having a ball grid array (BGA) with solder balls connected to distal lead ends. The lead frame has a peripheral portion at a higher position, the distal ends of the leads 205 are lowered, and solder balls 217 are connected to the distal ends of the leads 205. Projecting electrodes 209 are formed on electrodes 208 of the first semiconductor chip 211 and are connected to ends of the leads 205 in a state that the wiring plane is facing downward (in a flip-chip shape). Thereafter, the first semiconductor chip 211 is molded with first sealing resin 202, with the solder balls 217 being exposed. The bottom of the second semiconductor chip 212 is bonded to the bottom of the first semiconductor chip 211 via an insulating bonding member 280. The electrodes 218 of the second semiconductor chip 212 are connected to the leads of the lead frame by bonding wires 214. The second semiconductor chip 212 and bonding wires 214 are molded with second sealing resin 203. The unnecessary portion of the lead frame is thereafter cut off.

In the structure illustrated in FIG. 8B, two semiconductor chips are coupled back to back, and two circuit planes are disposed on opposite sides of the two semiconductor chips. Electrodes 208 on one circuit plane are connected via projecting electrodes 209 to ball electrodes 217, and electrodes 218 are connected to ball electrodes 217 via bonding wires 214 and leads 205 of the lead frame. In the peripheral portion of the lead frame, a cut plane of the lead frame is exposed at the side wall of the package. In these structures, the bonding wires and solder balls are disposed on opposite sides of the interposer or semiconductor chip.

The structure that an interface between the sealing resin and lead frame or interposer is exposed at the side wall of the package is associated with some issues such as lowered reliability because of strip-off at the interface or because of moisture invasion from the interface, or conductive cutting scraps such as Cu which may be produced upon blade-dicing the package. There is also a fear of short circuit of the structure in case where leads of a lead frame are exposed at the side wall.

### SUMMARY

According to one aspect, a semiconductor device includes:

a first semiconductor chip having first input/output pads on a first surface thereof;

a first molding resin body surrounding side walls of the first semiconductor chip and having a subsidiary first surface extending from the first surface of the first semiconductor chip toward outside;

a second semiconductor chip having second input/output pads on a second surface thereof and stacked above the first semiconductor chip, with the second surface directed upward;

a second molding resin body molding the second semiconductor chip and coupled with the first molding resin body in an area outside the first semiconductor chip;

first wirings connected to at least some of the first input/output pads of the first semiconductor chip or the second input/output pads of the second semiconductor chip, and extending along the subsidiary first surface of the first molding resin body or along the second surface of the second semiconductor chip or along an extension of the second surface of the second semiconductor chip;

external connection metal posts formed on the wirings each having a top portion exposed from the second molding resin body; and

ball-shaped external connection terminals connected to the external connection metal posts.

The object and advantages of the invention will be realized and attained by means of the elements and combinations particularly pointed out in the claims.

It is to be understood that both the foregoing general description and the following detailed description are exemplary and are not restrictive of the invention, as claimed.

### BRIEF DESCRIPTION OF DRAWINGS

FIGS. 1A, 1B, 1C, 1D and 1E are cross sectional views and plan views of a semiconductor device according to a first embodiment.

FIGS. 2A to 2N are cross sectional views illustrating main manufacture processes for the semiconductor device according to the first embodiment illustrated in FIGS. 1A to 1E.

FIG. 3 is a cross sectional view of a semiconductor device according to a second embodiment.

FIG. 4 is a cross sectional view of a semiconductor device according to a third embodiment.

FIGS. 5A and 5B are cross sectional view of a semiconductor device according to a fourth embodiment and a cross sectional view illustrating its manufacture process.

FIGS. 6A and 6B are cross sectional view of a semiconductor device according to a fifth embodiment and a cross sectional view illustrating its manufacture process.

FIGS. 7A and 7B are a plan view and a cross sectional view illustrating a modification of the semiconductor device.

FIGS. 8A and 8B are cross sectional views illustrating semiconductor devices according to conventional techniques.

### DESCRIPTION OF EMBODIMENTS

Description will now be made on the embodiments of a semiconductor device with reference to the accompanying drawings.

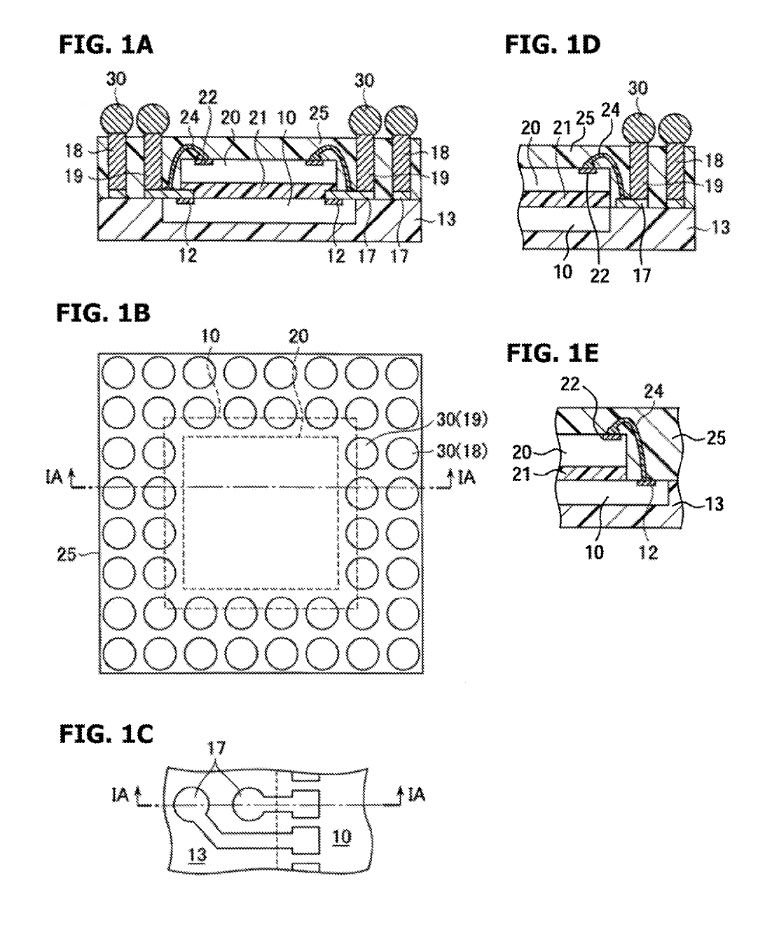

As illustrated in FIG. 1A, the bottom and side walls of a first semiconductor chip 10 are sealed with a first molding resin body 13 such as epoxy resin, with an active plane formed with input/output pads 12, MOS transistors and the like facing upward, and the upper surface of the molding resin body 13 is located fundamentally at the same level as that of the upper surface of the first semiconductor chip 10, i.e. being flush with the upper surface of the first semiconductor chip 10. A rewiring layer 17 of cupper or the like is formed extending in a predetermined pattern on the upper surfaces of the input/output pads 12 on the first semiconductor chip 10 and molding resin body 13. Metal posts 18 and 19 of cupper or the like are formed on the rewiring layer 17. The molding resin layer 13 covers the side walls and bottom of the first semiconductor chip 10. The rewiring layer 17 is extended from the upper surface of the first semiconductor chip 10 to the upper surface of the molding resin body 13, and metal posts 18, 19 are formed on ends thereof. It is thus possible to dispose a second semiconductor chip above the first semiconductor chip without being restricted by the positions of the input/output pads of the first semiconductor chip.

A second semiconductor chip 20 having an insulating die attachment film 21 bonded to the bottom surface is bonded to the upper surface of a first semiconductor chip 10 through the die attachment film 21, with an active plane formed with input/output pads 22, MOS transistors and the like being turned upward. The die attachment film 21 is made of, e.g., glass epoxy or polyimide. Input/output pads 22 of the second semiconductor chip 20 are connected to the rewiring layer 17 by bonding wires 24 such as gold wires. Interconnection between the first and second semiconductor chips 10 and 20 is realized by the bonding wires 24 and rewiring layers 17.

As illustrated in FIG. 1D, if the input/output pad 22 of the second semiconductor chip 20 is to be led to an external position via the rewiring layer 17, the rewiring layer 17 may not be connected to the input/output pad 12 of the first semiconductor chip 10.

The second semiconductor chip may be located, exposing at least portion of the input/output pads of the first semiconductor chip.

As illustrated in FIG. 1E, an input/output pad 22 of the second semiconductor chip 20 may be connected to the input/output pad 12 of the first semiconductor chip 10 by a bonding wire 24. The rewiring layer 17 may be formed only in necessary areas.

A second molding resin body 25 such as epoxy resin seals the second semiconductor chip 20, rewiring layer 17, bonding wires 24 and metal posts 18 and 19 other than the upper end portions. Solder balls or the like (ball-like electrodes) as external connection terminals 30 are connected to the upper surfaces of the exposed metal posts 18 and 19.

FIG. 1B is a plan view illustrating the layout of external connection terminals 30 on the second molding resin body 25 (metal posts 18 and 19 are under the external connection terminals 30) together with the positions of the first semiconductor chip 10 and second semiconductor chip 20. FIG. 1A is a cross sectional view taken along line 1A-1A. External connection terminals 30 are disposed on the second molding resin body 25 surrounding the second semiconductor chip 20 in double rows of loop shape. Although drawn schematically, the number of actual external connection terminals is, e.g., 100 or more and smaller than about 1000. The layout is not limited to double rows of loop shape.

FIG. 1C is a schematic plan view illustrating an example of a pattern of the rewiring layer 17. The rewiring layer 17 leads the input/output pads 12 on the upper surface of the first semiconductor chip 10 to the upper surface of the molding resin body 13.

In this embodiment, the upper surface of the lower semiconductor chip is made flush with the upper surface of the lower molding resin body, and at least some input/output pads of the lower semiconductor chip are lead to the upper surface of the lower molding resin body via the rewiring layer. The upper semiconductor chip is bonded to the upper surface of the lower semiconductor chip via the die attachment film, and at least some input/output pads of the lower semiconductor chip are connected to the rewiring layers by bonding wires. The upper molding resin body molds the upper semiconductor chip, bonding wires and rewiring layers, and is coupled to the lower molding resin body. The metal posts for external connections extend through the upper molding resin body to be connected to the rewiring layers.

The whole surfaces of the first and second semiconductor chips 10 and 20 are covered with the molding resin bodies 13 and 25. An interface between the molding resin body and other members does not exist at the outer surface of the package, except the interface between the metal posts 18 and 19 and molding resin body 25. In order to prevent strip-off and moisture invasion, it is preferable to set a distance between the outer surface (particularly side wall) of the molding resin bodies 13 and 25 to the rewiring layer 17, upper semiconductor chip 20 and lower semiconductor chip 10 to 300 microns or longer. Since the metal posts 18 and 19 are covered with the molding resin body 25, strip-off at the interface is hard to occur. Even if moisture invades from the interface between the metal posts 18 and 19 and the molding resin body, a possibility of adverse effects is suppressed.

Conductor will not be exposed at the side wall of the semiconductor package, when packages are separated, conductive cutting scraps will not be produced, and there is no fear of short circuit even a plurality of packages are disposed side by side. Since the stacked semiconductor chips are sandwiched between the upper and lower molding resin bodies, it is possible to suppress warping to be caused by unbalanced stresses.

The following features are obtained from the embodiment, which is common also to the following embodiments: In the structure that semiconductor chips are stacked and sealed with resin, although an interface between molding resin bodies exists at the side walls of the package, an interface between the molding member and another member of materials different from the molding resin body does not exists, it is therefore possible to suppress lowering of the reliability.

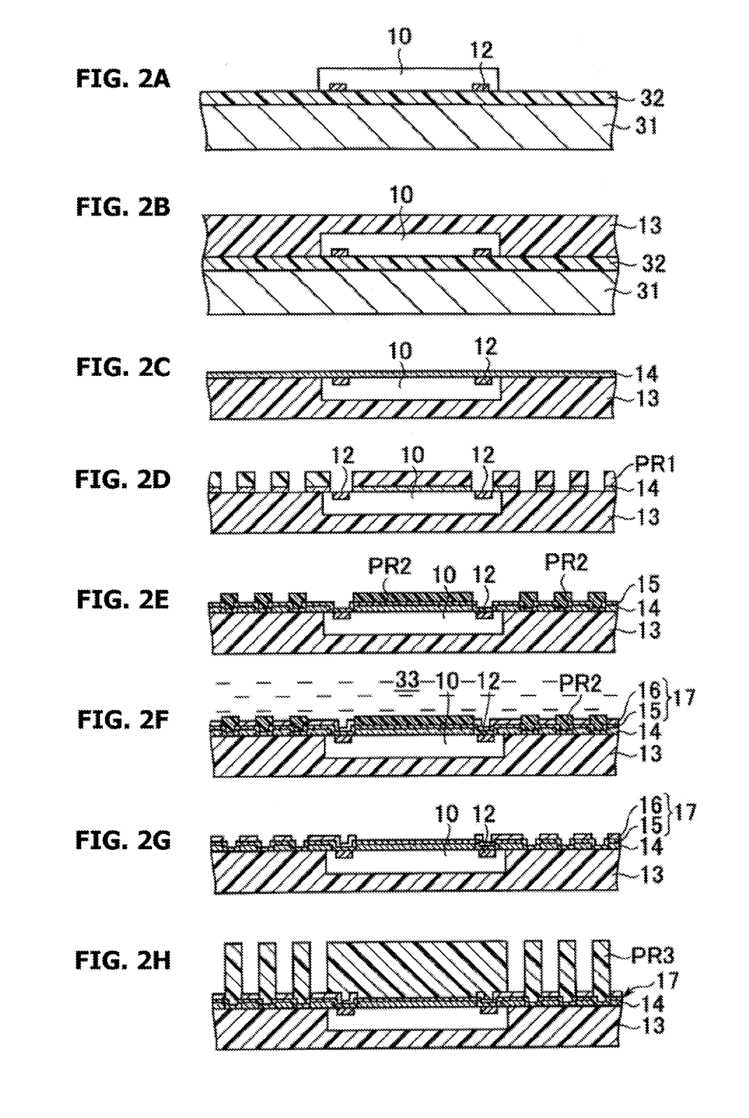

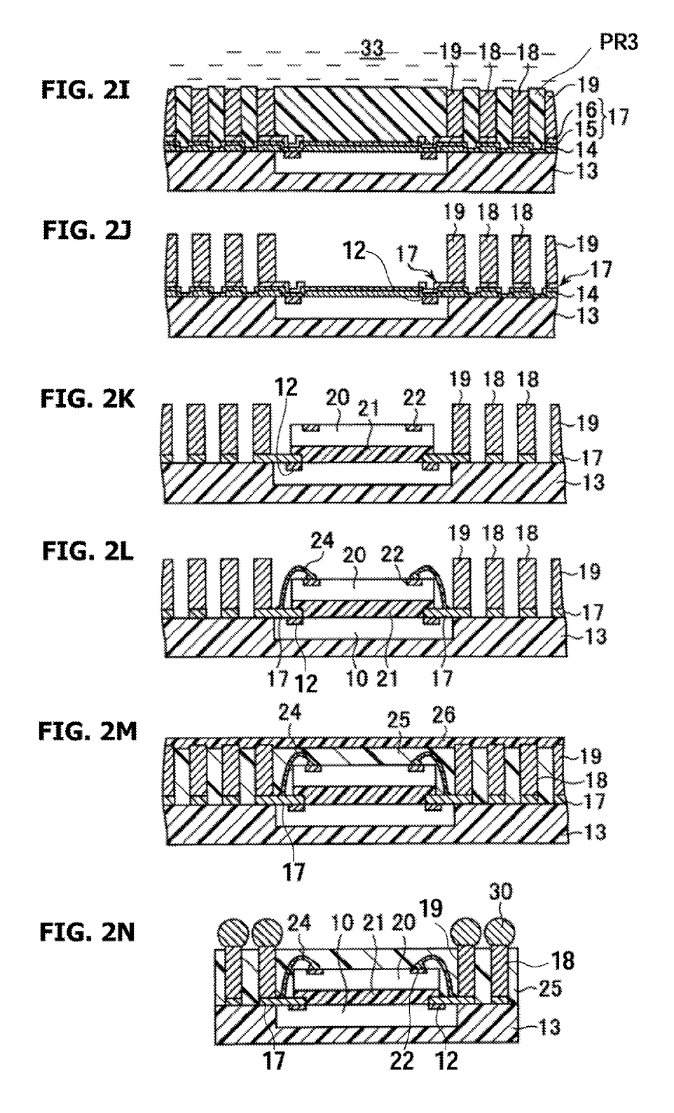

Manufacture processes for the semiconductor device illustrated in FIGS. 1A and 1B will be described with reference to FIGS. 2A to 2N.

As illustrated in FIG. 2A, an adhesive sheet 32 is attached to the dummy substrate 31, and a first semiconductor chip 10 is bonded in an inverted state (an upside-down state). The dummy substrate 31 is a physical support member to be removed later, and may be made of a silicon substrate, a stainless steel plate or the like. The adhesive sheet 32 is, e.g., a heat peelable sheet REVALPHA manufactured by Nitto Kogyo. The rear side of the first semiconductor chip 10 may be polished beforehand to reduce its thickness to a desired value.

As illustrated in FIG. 2B, the first semiconductor chip 10 fixed to the dummy substrate 31 via the adhesive sheet 32 is sealed with a molding resin body 13 in a mold of injection molding. The circuit plane of the first semiconductor chip 10 and the surface (bottom in the drawing) of the molding resin body 13 are fundamentally at the same plane (flush together). Thereafter, the dummy substrate 31 is peeled off together with the adhesive sheet 32, e.g., which is a heat peelable sheet. The same dummy substrate 31 may be reused.

As illustrated in FIG. 2C, an insulating film 14 is coated on the surfaces of the first semiconductor chip 10 and molding resin body 13. For example, an inorganic insulating film, for example of spin-on-glass (SOG) or an organic insulating film, for example of polyimide is formed.

As illustrated in FIG. 2D, a resist pattern PR1 for patterning the insulating film 14 is formed, and the insulating film 14 is etched to expose the input/output pads 12. The insulating films 14 in the areas on which rewiring layers are to be disposed are also removed. Thereafter, the resist pattern PR1 is removed.

As illustrated in FIG. 2E, an underlying metal layer 15 such as TiN and Cu is formed on the whole surface by sputtering or the like. The underlying metal layer is a conductive layer to be used as an current electrode in an electrolytic plating process. A resist pattern PR2 is formed on the underlying metal layer 15, having openings in the areas where plating is to be performed.

As illustrated in FIG. 2F, the structure including the first semiconductor chip 10, molding resin body 13 and the related members is immersed in plating liquid 33, and electrolytic plating is performed to form a rewiring layer 16 such as Cu on the underlying metal layer 15. The rewiring layer 16 is connected to the input/output pads 12. Since the underlying metal layer 15 functions also as the wiring layer, the metal layers 15 and 16 are collectively used as the rewiring layer 17. In the state illustrated, all rewiring layers 16 are in a state short-circuited by the underlying metal layer 15.

As illustrated in FIG. 2G, the structure including the first semiconductor chip 10, molding resin body 13, rewiring layer 17 and the related members are picked up from the plating liquid 33, and the resist pattern PR2 is thereafter removed.

As illustrated in FIG. 2H, a resist pattern PR3 having openings (holes) for forming metal posts on the rewiring layer 17 is formed on the structure. Openings for adjacent packages are also illustrated.

As illustrated in FIG. 2I, the structure including the first semiconductor chip 10 and molding resin body 13 is immersed again in the plating liquid 33 to perform electrolytic plating and form metal posts 18 and 19 of Cu or the like on the rewiring layer 17. The structure is picked up thereafter from the plating liquid.

As illustrated in FIG. 2J, the resist pattern PR 3 is removed. The exposed underlying metal layer 15 is etched and removed. Wiring configuration in which each rewiring layer 17 is electrically separated, and the input/output pads 12 are led upward through the rewiring layer 17 and metal posts 18 and 19. The rewiring layers 17 have the shape as illustrated in FIG. 1C. In the drawings to follow, the insulating layer 14 is not drawn, and the metal layers 15 and 16 are collectively illustrated as the rewiring layer 17.

As illustrated in FIG. 2K, a second semiconductor chip 20 having a rear side back-ground and a die attachment film 21 bonded thereon is bonded to the central area of the first semiconductor chip, in an erected (upside-up, or principal surface formed with active elements directed upward) state with the input/output pads directed upward.

As illustrated in FIG. 2L, the input/output pads 22 of the second semiconductor chip 20 are connected to predetermined rewiring layers 17 by bonding wires 24. If the input/output pads 12 of the first semiconductor chip 10 are exposed, the input/output pads 22 and input/output pads 12 may be wire-bonded.

As illustrated in FIG. 2M, an adhesive sheet 26 is disposed in a mold to cover the upper surfaces of the metal posts 18 and 19. Then, the second semiconductor chip 20, bonding wires 24, rewiring layer 17 and metal posts 18 and 19 are sealed with a molding resin body 25. The adhesive sheet 26 is, e.g., a heat peelable sheet REVALPHA manufactured by Nitto Kogyo. The molding resin body will not attach on the upper surfaces of the metal posts 18 and 19 which are covered with the adhesive sheet.

As illustrated in FIG. 2N, the adhesive sheet 26 is peeled off, and solder balls or the like as external connection terminals 30 are connected to the top surfaces of the metal posts 18 and 19. Thereafter, the molding resin bodies 25 and 13 are diced to form individual semiconductor packages. Neither semiconductor nor metal does exist in the dicing region.

In the first embodiment, the rewiring layer is formed from on the lower semiconductor chip toward the outside, and the metal posts and external connection terminals are located on the rewiring layer, outside the upper semiconductor chip. The external connection terminals may also be disposed in an inner area.

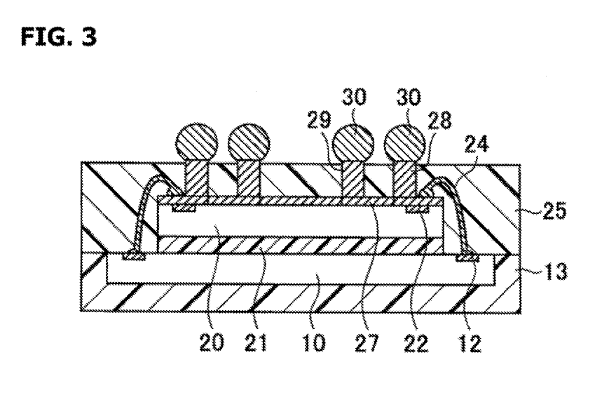

FIG. 3 is a cross sectional view of a semiconductor device according to the second embodiment. Similar to the first embodiment, the rear surface of a second semiconductor chip 20 is die-bonded via a die attachment film 21 to the front (circuit) surface of a first semiconductor chip 10, the bottom and side walls of which are sealed with a first molding resin body 13. In the second embodiment, metal posts 28 and 29 are formed on the second semiconductor chip 20. It is preferable that the rewiring layers 27 and metal posts 28 and 29 are formed beforehand on the second semiconductor chip 20.

In a wafer state, the rewiring layers 27 and metal posts 28 and 29 are formed on the surface area corresponding to each chip which will become the second semiconductor chip. The area corresponding to each chip is diced from the wafer, to provide the second semiconductor chip 20. The input/output pads 12 of the first semiconductor chip 10 and the predetermined rewiring layers 27 on the second semiconductor chip 20 or input/output pads 22 are interconnected by bonding wires 24. Thereafter, the second semiconductor chip 20 is buried in a second resin body 25 as illustrated in FIG. 2M, exposing the top surfaces of the metal posts 28 and 29, and external connection terminals 30 are connected to the top surfaces of the metal posts 28 and 29.

The second embodiment assumes that the lower semiconductor chip 10 is larger than the upper semiconductor chip 10 to allow direct connection of bonding wires to the input/output pads 12 of the lower semiconductor chip 10. This second embodiment method is not applicable if the lower semiconductor chip 10 has the size of the same degree as the upper lower semiconductor chip 20 or smaller than the upper semiconductor chip 20.

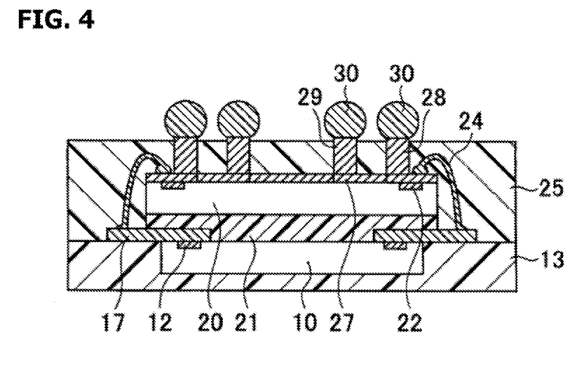

FIG. 4 is a cross sectional view of a semiconductor device according to the third embodiment in which a lower semiconductor chip 10 is smaller than an upper semiconductor chip 20. After a first molding resin body 13 is formed covering the bottom and side walls of the lower semiconductor chip 10, first rewiring layers 17 are formed to lead out the input/output pads 12 of the lower semiconductor chip 10 to the outside of the lower semiconductor chip 10. Thereafter, similar to the second embodiment, the upper semiconductor chip 20 formed with the rewiring layers 27 and metal posts 28 and 29 is die-bonded on the first semiconductor chip 10. In this state, the lower rewiring layers 17 led from the upper surface of the lower first semiconductor chip 10 to the upper surface of the first molding resin body 13, extend to the outside of the second semiconductor chip. The lower rewiring layers 17 and the predetermined upper rewiring layers 27 or input/output pads are interconnected by bonding wires 24. Other points are similar to the second embodiment.

In the third embodiment, two rewiring layers are formed at the surface levels of the first semiconductor chip and the second semiconductor chip. As the two rewiring layers are formed, it is possible to improve the freedom of design and remove restrictions of relative sizes of the upper and lower semiconductor chips.

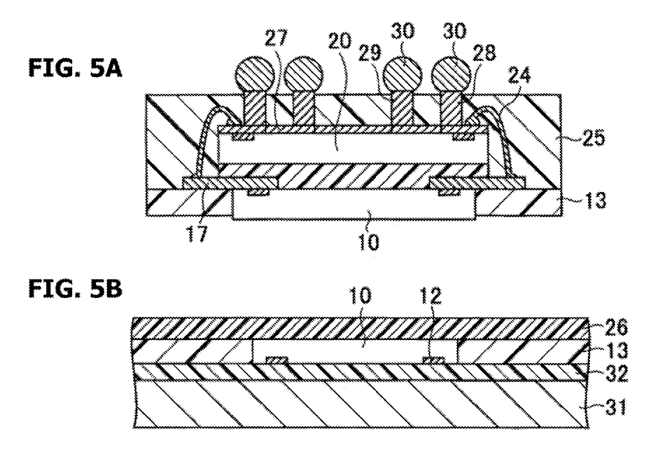

FIG. 5A is a cross sectional view of a semiconductor device according to the fourth embodiment. In this embodiment, the bottom of a lower semiconductor chip 10 is exposed. For example, a structure in which the first molding resin body 13 of the third embodiment is removed from the rear surface of the first semiconductor chip 10. Similarly, in other embodiments, the rear surface of the first semiconductor chip disposed in a lower position may be exposed.

As illustrated in FIG. 5B, a front surface of a first semiconductor chip 10 is bonded to a dummy substrate 31 via an adhesive sheet 32, and an adhesive sheet 26 is disposed in a mold on a side of the rear surface of the first semiconductor chip 10. Then, sealing of the first semiconductor chip 10 with a first molding resin body 13 is done. As the adhesive sheet 26 is peeled off, the bottom of the first semiconductor chip 10 is exposed. This state corresponds to the state illustrated in FIG. 2B, except the exposure or the rear surface of the first semiconductor chip. Thereafter, processes corresponding to each embodiment may be performed.

Since the bottom of the first semiconductor chip is exposed, it is possible to promote heat radiation from the first semiconductor chip. For example, the exposed bottom of the first semiconductor chip is thermally coupled to a heat radiation or heat sink structure. The structure according to the fourth embodiment is suitable for a semiconductor chip having large heat generation capability.

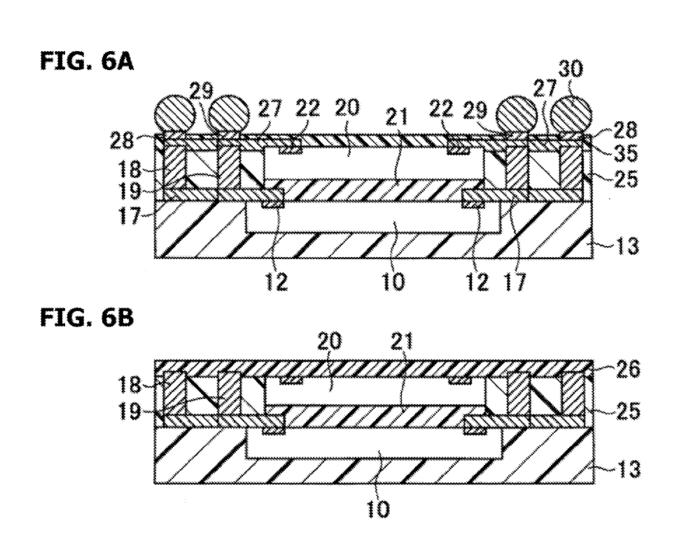

FIG. 6A is a cross sectional view of a semiconductor device according to the fifth embodiment. In the fifth embodiment, bonding wires are not used, and the input/output pads of a first semiconductor chip are connected to the input/output pads of a second semiconductor chip through rewiring layers and metal posts. Similar to the first embodiment, the periphery of the first semiconductor chip 10 is surrounded by a first molding resin body 13, and first rewiring layers 17 are formed from on the first semiconductor chip to on the first molding resin body. First metal posts 18 and 19 are formed on the first rewiring layers 17, without performing wire bonding. A second semiconductor chip 20 is die-bonded to the first semiconductor chip 10 via a die attachment film 21, and a second molding resin body 25 is formed.

As illustrated in FIG. 6B, an adhesive sheet 26 is disposed in a mold, covering the upper surfaces of the second semiconductor chip 20 and metal posts 18 and 19, and sealing of the second semiconductor chip with the molding resin body 25 is performed. As the adhesive sheet 26 is peeled off, the upper surfaces of the second semiconductor chip 20 and metal posts 18 and 19 are exposed.

As illustrated in FIG. 6A, second rewiring layers 27 are formed on the second semiconductor chip 20 and molding resin body 25, to connect the input/output pads 22 of the second semiconductor chip 20 with the metal posts 18 and 19. The metal posts 18 and 19 are used for internal connection. External connection metal posts 28 and 29 are formed on the second rewiring layers 27. A third molding resin body 35 of epoxy resin or the like is formed by spin coating, injection molding or the like, burying the second rewiring layers 27 and exposing the top portions of the external connection metal posts 28 and 29. External connection terminals 30 are connected to the top surfaces of the metal posts 28 and 29.

The layout of metal posts and external connection terminals may be altered.

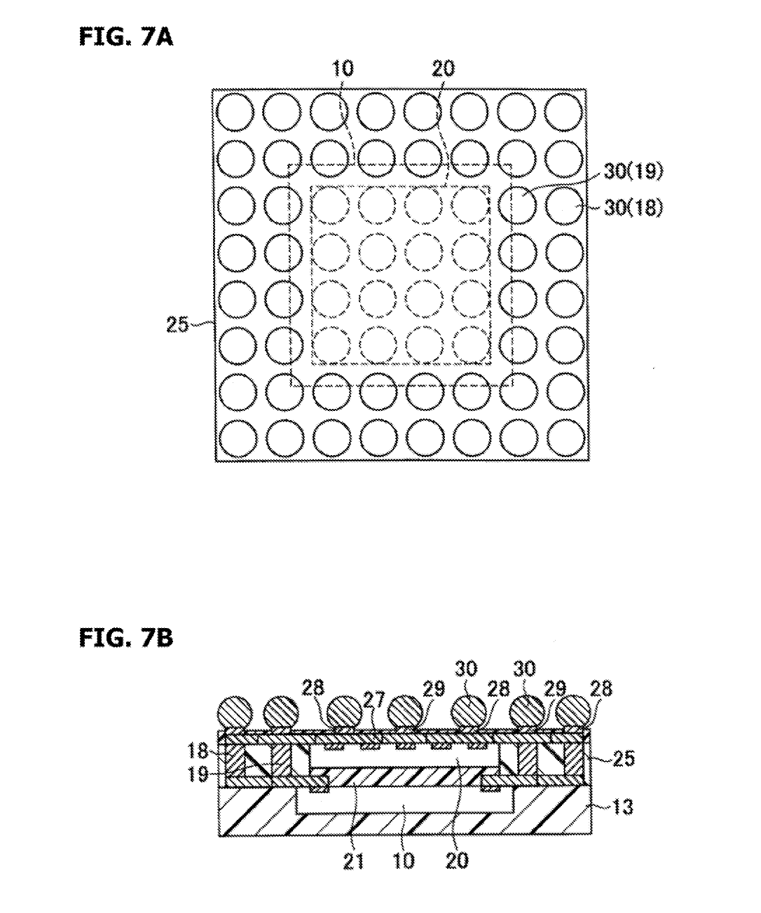

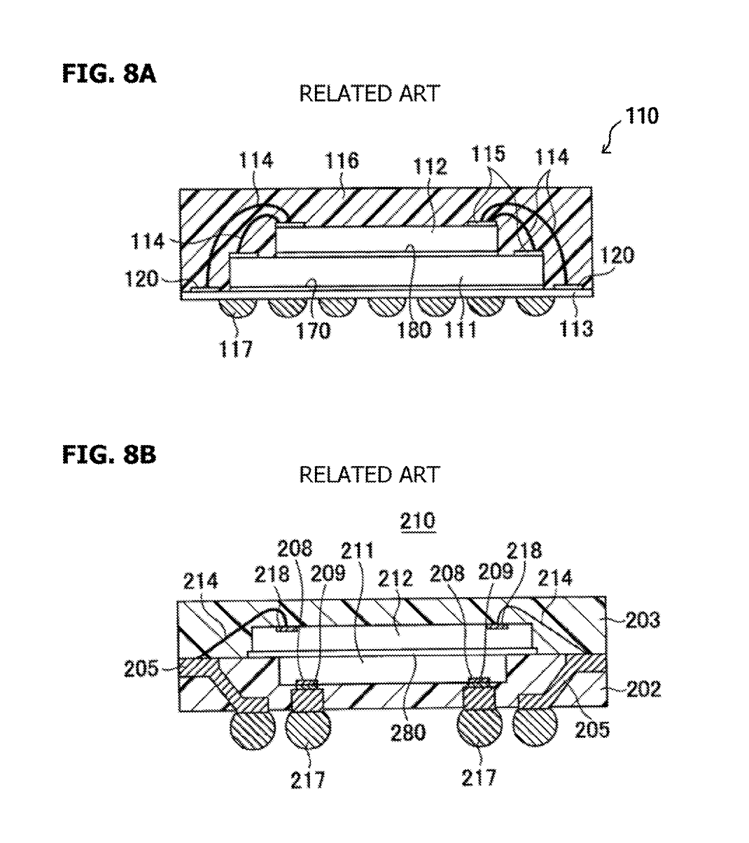

FIG. 7A illustrates a configuration in which outer metal posts 18 and inner metal posts 19 are aligned horizontally and vertically in the figure. External connection terminals 30 are formed on the metal posts. Although the metal posts and external connection terminals are disposed in an area outside the semiconductor chip, the posts and terminals may also be disposed in an area inside the semiconductor chip similar to the second, third and fourth embodiments, as illustrated by broken lines. It is also possible to dispose the external connection terminals on the whole upper surface of the package.

FIG. 7B illustrates a modification of the fifth embodiment. Rewiring layers 27, metal posts 28 and 29 and external connection terminals 30 are disposed also above an upper semiconductor chip 20. This structure is suitable for an increase in the number of pins.

All examples and conditional language recited herein are intended for pedagogical purposes to aid the reader furthering the art, and are construed as being without limitation to such specifically recited examples and conditions, nor does the organization of such examples relate to a showing of the superiority and inferiority of the invention. Although the embodiments of the present invention have been described in detail, it should be understood that the various changes, substitutions, and alterations could be made hereto without departing from the spirit and scope of the invention.

What we claim are:

1. A semiconductor device comprising:
a first semiconductor chip having first input/output pads on a first surface thereof;
a first molding resin body surrounding side walls of the first semiconductor chip and having a subsidiary first surface extending from the first surface of the first semiconductor chip toward outside;
a second semiconductor chip having second input/output pads on a second surface thereof and stacked above the first semiconductor chip, with the second surface directed upward;
a second molding resin body molding the second semiconductor chip and coupled with the first molding resin body in an area outside the first semiconductor chip;
first wirings connected to at least some of the first input/output pads of the first semiconductor chip or the second input/output pads of the second semiconductor chip, and extending along the subsidiary first surface of the first molding resin body or along the second surface of the second semiconductor chip or along an extension of the second surface of the second semiconductor chip;
external connection metal posts formed on the wirings each having a top portion exposed from the second molding resin body; and
ball-shaped external connection terminals connected to the external connection metal posts.

2. The semiconductor device according to claim 1, wherein:
the first wirings are connected with the first input/output pads of the first semiconductor chip and extend along the subsidiary first surface of the first molding resin body, and the external connection posts are disposed on the first wirings and extending through the second molding resin body.

3. The semiconductor device according to claim 2, further comprising first bonding wires connecting second input/output pads of the second semiconductor chip with the first wirings.

4. The semiconductor device according to claim 1, wherein:
the first wirings are connected with the second input/output pads of the second semiconductor chip and extend along the second surface and extension thereof of the second semiconductor chip, and the external connection metal posts are disposed on the first wirings and extend through an upper portion of the second molding resin body.

5. The semiconductor device according to claim 4, further comprising second bonding wires connecting the first input/output pads of the first semiconductor chip and the first wirings.

6. The semiconductor device according to claim 4, further comprising:
second wirings connected with the first input/output pads of the first semiconductor chip and extend along the subsidiary first surface of the first molding resin body; and
connection members electrically connecting the second wirings and the second input/output pads of the second semiconductor chip.

7. The semiconductor device according to claim 6, wherein:
the second wirings and the first wirings have overlapping portions as viewed in plan; and
the connection members include internal connection metal posts connected to the first wirings.

8. The semiconductor device according to claim 7, wherein:
the second molding resin body comprises a lower second molding resin body from a surface level of the first molding resin body to a level of the second surface the second semiconductor chip and an upper second molding resin body from a surface level of the lower second molding resin body to a surface level of the second molding resin body.

9. The semiconductor device according to claim 1, further comprising metal conductive members for electrically connecting the first input/output pads of the first semiconductor chip and the second input/output pads of the second semiconductor chip.

10. The semiconductor device according to claim 1, wherein the first molding resin body is formed only on the side walls of the first semiconductor chip and not on a bottom thereof.

11. A method for manufacturing a semiconductor device comprising:
forming a first molding resin body surrounding side walls of a first semiconductor chip having first input/output pads on a first surface thereof, and having a subsidiary first surface extending from the first surface of the first semiconductor chip toward outside;
die-bonding a second semiconductor chip having second input/output pads on a second surface thereof above the first semiconductor chip with the second surface directed upward;
forming a second molding resin body molding the second semiconductor chip and coupled with the first molding resin body in an area outside the first semiconductor chip;
forming first wirings connected to at least some of the first input/output pads of the first semiconductor chip or the second input/output pads of the second semiconductor chip, and extending along the subsidiary first surface of the first molding resin body or along the second surface of the second semiconductor chip or along extension of the second surface of the second semiconductor chip;
forming external connection metal posts on the first wirings each having a top portion exposed from the second molding resin body; and
connecting ball-shaped external connection terminals on the external connection metal posts.

12. The method for manufacturing a semiconductor device according to claim 11, wherein:
when the first molding resin body is formed, the first semiconductor chip having first input/output pads on the first surface thereof is fixed in an upside-down state above a dummy substrate; the first semiconductor chip above the dummy substrate is molded with a first molding resin body; and the dummy substrate is removed.

13. The method for manufacturing a semiconductor device according to claim 12, wherein: the first semiconductor chip is fixed to the dummy substrate with an adhesive sheet.

14. The method for manufacturing a semiconductor device according to claim 11, wherein:
when the first wirings are formed, the first wirings are formed connected with the first input/output pads of the first semiconductor chip and extend along the subsidiary first surface of the first molding resin body;
the external connection metal posts are formed on the first wirings before die-bonding of the second semiconductor chip;
when the second molding resin body is formed, the second molding resin body is formed molding the second semiconductor chip and the first wirings, and molding lower portions of the external connection metal posts, while exposing top portions of the external connection metal posts.

15. The method for manufacturing a semiconductor device according to claim 14, wherein: before the second molding resin body is formed, the second input/output pads of the second semiconductor chip are wire bonded to the first wirings.

16. The method for manufacturing a semiconductor device according to claim 11, wherein: when the first molding resin body is molded, a bottom of the first semiconductor chip is covered with an adhesive sheet.

17. The method for manufacturing a semiconductor device according to claim 11, wherein: the first wirings and the external connection metal posts are formed by plating using a resist pattern.

18. The method for manufacturing a semiconductor device according to claim 11, wherein: the first wirings are formed above the second surface of the second semiconductor chip, and the external connection posts are formed on the first wirings; and
when the second molding resin body is formed, the second molding resin body molds the second semiconductor chip, while exposing top portions of the external connection metal posts.

19. The method for manufacturing a semiconductor device according to claim 18, further comprising:
after die-bonding the second semiconductor chip, and before forming the second molding resin body, wire-bonding the first input/output pads of the first semiconductor chip, with the first wirings or second input/output pads of the second semiconductor chip.

20. The method for manufacturing a semiconductor device according to claim 12, further comprising:
before the second semiconductor chip is die-bonded, forming second wirings connected with the first input/output pads of the first semiconductor chip and extending along the subsidiary first surface of the first molding resin body; and
forming internal connection metal posts on the second wirings;
wherein the forming the second molding resin body
forms a lower second molding resin body molding side walls of the second semiconductor chip, while exposing the second surface of the second semiconductor chip and top surfaces of the internal connection metal posts, and forming a subsidiary second surface of the lower second molding resin body extending from the second surface of the second semiconductor chip toward outside, and
thereafter forms an upper second molding resin body above the lower second molding resin body;
the forming the first wirings forms the first wirings extending from the second input/output pads of the second semiconductor chip along the subsidiary second surface of the lower second molding resin body and connected to the internal connection metal posts.
